(19) United States
(12) Patent Application Publication
(10) Pub. No.: US 2005/0211977 A1
(43) Pub. Date: Sep. 29, 2005

(54) Organic semiconductor device and method of producing the same

(75) Inventors: Tadahiko Hirai, Ohta-ku (JP); Mitsumasa Iwamoto, Ohta-ku (JP); Takaaki Manaka, Kawasaki (JP)

Correspondence Address: FITZPATRICK CELLA HARPER & SCINTO, 30 ROCKEFELLER PLAZA, NEW YORK, NY, 10112, US

(73) Assignee: Canon Kabushiki Kaisha, Tokyo (JP)

(21) Appl. No.: 11/082,658

(22) Filed: Mar. 18, 2005

(30) Foreign Application Priority Data
Mar. 26, 2004 (JP) 2004-091573

(51) Int. Cl. H01L 35/24; H01L 21/00

(52) U.S. Cl. 257/40; 438/82

(57) ABSTRACT

The organic semiconductor device of the present invention includes an organic semiconductor material and a conductive electrode contacting with the organic semiconductor material, wherein a quasi Fermi level of the organic semiconductor material and a Fermi level of the conductive electrode are optimized by using adjustment means, and a junction barrier between the organic semiconductor material and the conductive electrode is controlled.

### BACKGROUND OF THE INVENTION

1. Field of the Invention

The present invention relates to an organic semiconductor device having good characteristics of carrier injection and to a method of producing the same.

2. Related Background Art

In recent years, devices employing organic compounds as materials have been developed extensively, and devices such as an organic light-emitting diode, an organic thin film transistor, and an organic solar cell have been developed actively for practical use. Of those, the organic thin film transistor may not require a high temperature process for formation of an organic semiconductor film. Thus, the formation of the organic thin film has attracted attention as a low cost process technique allowing formation of a device on a resin substrate.

However, an organic semiconductor differs from an inorganic semiconductor, and behaviors of the organic semiconductor are hardly explained using an energy band structure generating from a periodic structure of a crystal system and using an electron gas model. Thus, a Fermi level of an electron in the organic semiconductor is also hardly defined.

For designing a semiconductor device, it is necessary to precisely control a carrier level of an electrode and a carrier level of an organic semiconductor in order to allow efficient flow of a carrier into the organic semiconductor from the electrode and to suppress a potential barrier between the electrode and the semiconductor to minimum. The conventional method of controlling these levels is only a method of measuring an energy (work function) required for emission of electrons at a surface of the electrode and at the surface of the organic semiconductor by a photoemission process or the like, and predicting a potential barrier at the junction of these surfaces (Japanese Patent Application Laid-Open No. H09-063771; and “Data book on work function of organic thin films,” CMC Publishing Co., Ltd.).

### SUMMARY OF THE INVENTION

An object of the present invention is to provide an organic semiconductor device including an organic semiconductor material and a conductive electrode contacting with the organic semiconductor device and capable of increasing a density of carriers flowing between the organic semiconductor material and the conductive electrode; and a method of producing the organic semiconductor device.

That is, the organic semiconductor device of the present invention includes an organic semiconductor material and a conductive electrode contacting with the organic semiconductor material, wherein a quasi Fermi level of the organic semiconductor material and a Fermi level of the conductive electrode are optimized by using adjustment means, and a junction barrier between the organic semiconductor material and the conductive electrode is controlled.

Further, a method of the present invention of producing an organic semiconductor device including an organic semiconductor material and a conductive electrode contacting with the organic semiconductor material, includes: optimizing a quasi Fermi level of the organic semiconductor material and a Fermi level of the conductive electrode by adjustment means; and controlling a junction barrier between the organic semiconductor material and the conductive electrode.

According to the present invention, it is possible to provide an organic semiconductor device having good device characteristics and capable of increasing the density of carriers flowing between the organic semiconductor material and the conductive electrode and injecting carriers with high efficiency.

### BRIEF DESCRIPTION OF THE DRAWINGS

FIG. 1 is a schematic diagram explaining surface potential measurement according to the present invention;

FIG. 2 is a graph showing the results of the surface potential measurement according to the present invention;

FIGS. 3A, 3B and 3C are schematic diagrams showing a principle of work function measurement according to the present invention;

FIG. 4 is a schematic diagram showing standing time dependence of work function according to the present invention; and

FIG. 5 is a graph showing a relationship between energy levels according to the present invention.

### DESCRIPTION OF THE PREFERRED EMBODIMENTS

Hereinafter, the present invention will be described in detail.

An organic semiconductor device of the present invention includes an organic semiconductor material and a conductive electrode contacting with the organic semiconductor material and can increase a density of carriers flowing between the organic semiconductor material and the conductive electrode by optimizing a quasi Fermi level of the organic semiconductor material and a Fermi level of the conductive electrode by using adjustment means, and controlling a junction barrier between the organic semiconductor material and the conductive electrode.

Examples of the organic semiconductor material used for the organic semiconductor device according to the present invention include low-molecular-weight organic semiconductor compounds and high-molecular-weight organic semiconductor compounds. Specific examples thereof include polyconjugated organic compounds containing a π-electron conjugated bond such as anthracene, tetracene, pentacene, hexacene, heptacene, thiophene, phthalocyanine, and porphyrin; and π-conjugated polymer compounds such as polythiophene, polyacene, polyacetylene, and polyaniline.

Examples of the conductive electrode include materials having a high conductance such as noble metals including gold, silver and platinum, copper, aluminum, and calcium; conductive pastes containing the materials; and conductive polymers containing the materials.

The junction barrier may be understood as an energy barrier derived from a difference in work functions at a junction between inorganic semiconductors, a junction between an inorganic semiconductor and a metal material, or the like. The junction barrier at a junction between an organic semiconductor and a conductive material, typified by a junction between an organic semiconductor and a metal electrode is often explained based on the same idea.

The Fermi level may be interpreted as the maximum energy of an elementary particle (Fermion) following Fermi statistics such as an electron at absolute zero, and may be understood as energy providing a density of state of 0.5 at a temperature higher than absolute zero. The Fermi level of the conductive material such as a metal presumably has substantially the same value as that of a work function (energy required for electron emission) of an electron. Thus, the work function may be substituted for the Fermi level.

The quasi Fermi level may be understood as an energy level of the organic semiconductor at which carriers are injected without a barrier, and is not necessarily equal to the work function. For the organic semiconductor, an energy band structure and an electron gas model as established for an inorganic semiconductor are presumably not established, but levels similar to an energy band structure presumably exist for an organic semiconductor molecule itself. For a carrier such as an electron, a model similar to a uniform electron gas model is not established, and the carrier may be localized in the organic semiconductor molecule. Thus, a quasi Fermi level with a behavior similar to the behavior of a Fermi level of an inorganic semiconductor system is defined for carrier injection into the organic semiconductor.

In a semiconductor device, current flows between a conductive electrode and an organic semiconductor material in many cases. A potential barrier generates at an interface of the conductive electrode and the organic semiconductor material to inhibit motion of carriers and to considerably restrict characteristics of the semiconductor device. The Fermi level of the conductive electrode and the quasi Fermi level of the organic semiconductor material are optimized by “adjustment means,” to thereby allow injection of carriers with high density and high efficiency.

The adjustment means is preferably one selected from the group consisting of photoirradiation, plasma exposure, heating, washing with a liquid, and rubbing treatment. The photoirradiation refers to irradiation of infrared light, visible light, UV light, or the like, and particularly the Fermi level at the surface of the conductive electrode can be adjusted by irradiation of UV light. Similar effects can be obtained by treatment such as exposure to argon plasma, washing with a liquid such as a strong acid, or rubbing treatment of rubbing a surface with a felt or the like.

The adjustment means is preferably carried out on at least one of the surface of the organic semiconductor material and the surface of the conductive electrode.

The conductor electrode preferably contains least one metallic substance selected from the group consisting of gold, silver, platinum, copper, aluminum, and calcium.

A height of the junction barrier can be determined by measuring a surface electrostatic potential of the organic semiconductor material formed on the conductive electrode. When a potential barrier exists at a junction interface between a conductor and an organic semiconductor, carriers move through the interface to maintain the conductive electrode at a constant voltage. Further, when the organic semiconductor is floated, the organic semiconductor charges up by the height of the potential barrier to reach equilibrium. This actually results from the motion of the carriers to reach equilibrium with the potential barrier serving as a driving force. Thus, the measurement of the surface electrostatic potential of the organic semiconductor material may be regarded as direct measurement of the quasi Fermi level of the organic semiconductor material using the Fermi level of the conductive electrode as a reference.

The carriers can be injected efficiently with a height of the junction barrier of 0.5 eV or less.

Examples of the organic semiconductor device include a diode, a thin film transistor, a junction type transistor, and a solar cell. All devices require highly efficient carrier injection between the conductive electrode and the organic semiconductor material.

Further, the present invention can provide a method of producing an organic semiconductor device including an organic semiconductor material and a conductive electrode contacting with the organic semiconductor material and capable of increasing a density of carriers flowing between the organic semiconductor material and the conductive electrode by optimizing a quasi Fermi level of the organic semiconductor material and a Fermi level of the conductive electrode by using adjustment means; and controlling a junction barrier between the organic semiconductor material and the conductive electrode.

Hereinafter, the present invention will be described in more detail with reference to Examples.

### EXAMPLE 1

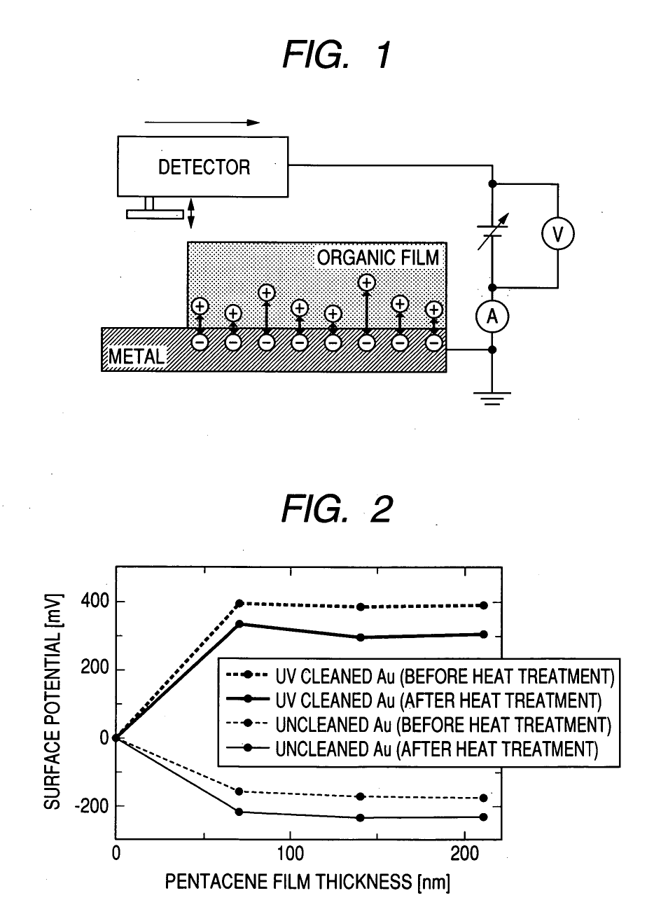

The concept and embodiment of the present invention are described referring to FIGS. 1 to 5.

FIG. 1 is a schematic diagram explaining measurement of an electrostatic potential generated at a surface of an organic semiconductor using a sample prepared by contacting a conductive electrode and an organic semiconductor material. A metallic thin film was used as a conductive material and was connected to the ground. A change in surface potential was measured by scanning from the surface of the metal to the surface of the organic semiconductor material using a Kelvin probe detector (probe).

FIG. 2 shows an example of the results of the surface potential measurement. A gold thin film was used as a conductive electrode material, and an vacuum-evaporated pentacene was used as an organic semiconductor material. Ultraviolet (UV) irradiation and heat treatment were used as adjustment means. A relationship between a surface electrostatic potential of the pentacene film, and a pentacene film thickness, use or disuse of UV irradiation (UV cleaning) to a gold electrode surface, and use or disuse of heat treatment on the gold electrode surface was measured. No significant relationship was apparent between the electrostatic potential and the pentacene film thickness, but the electrostatic potential was strongly affected by the use or disuse of the UV irradiation to the gold electrode surface.

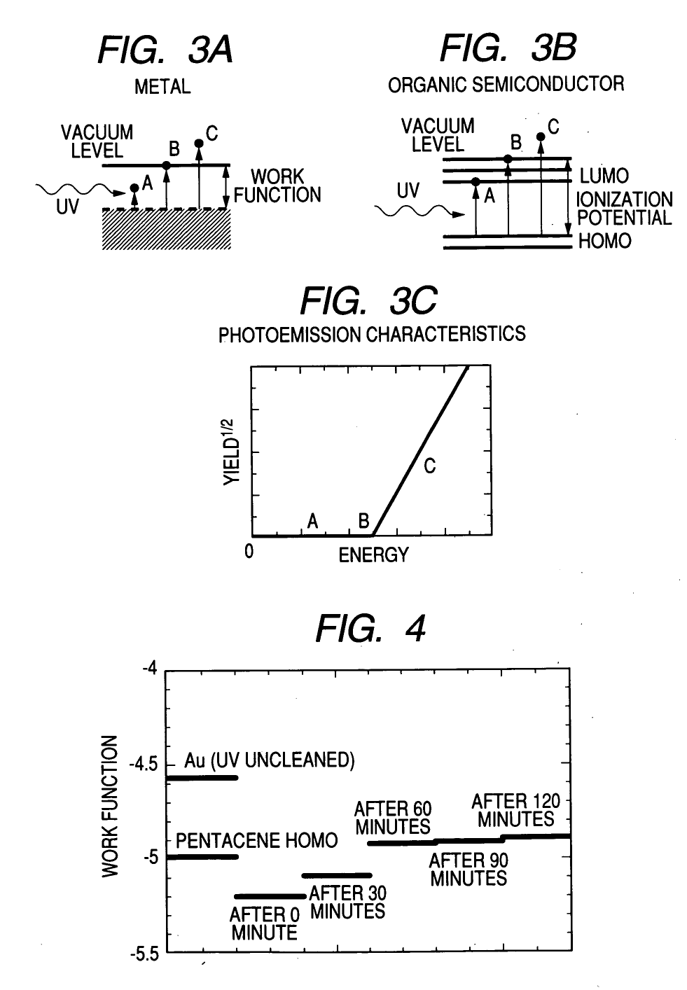

FIGS. 3A to 3C are schematic diagrams explaining work function measurement by photoelectron spectroscopy. A work function of the metal or the organic semiconductor can be measured by reading an energy value at a rise position of photoelectron current.

FIG. 4 is a schematic diagram showing a relationship between standing time and work function after subjecting the gold surface to UV irradiation (UV cleaning) and atmospheric standing. The work function continuously varies depending on standing time, and the work function can be adjusted by setting an arbitrary standing time. The results indicate that a junction barrier between the conductive electrode and the organic semiconductor material can be arbitrarily adjusted. Further, the work function can be adjusted by arbitrarily adjusting UV irradiation time or UV illuminance.

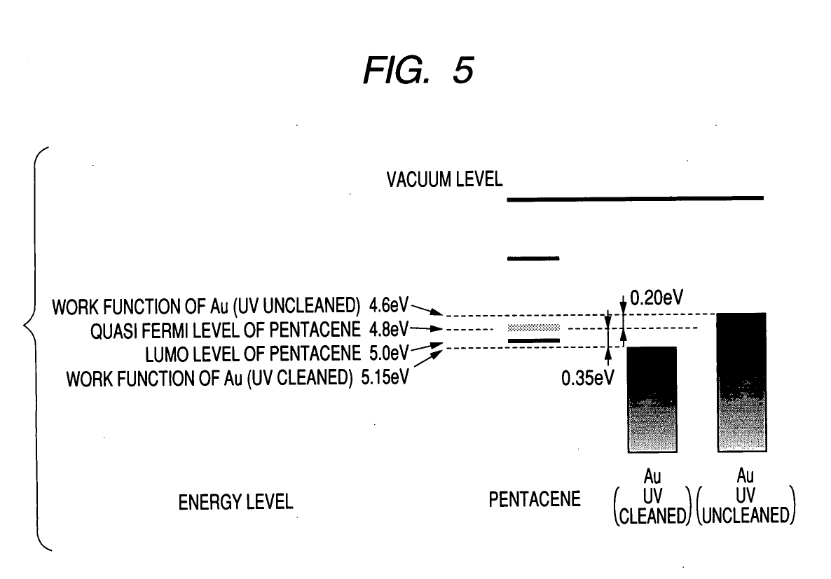

FIG. 5 is a graph summarizing the results of the measurement shown in FIGS. 1 to 4. The results reveal that an energy level at which a carrier moves in the organic semiconductor (pentacene) exists at about 4.8 eV, which is shallower by about 0.20 eV than an LUMO energy level (work function) of pentacene.

Based on the findings, silicon oxide (film thickness of 500 nm) as a gate insulating film was formed on a silicon substrate. Then, a gold source/drain electrode (gate length of 50 μm and a gate width of 3 mm) was formed, and electrical characteristics were evaluated. As a result, a gold source/drain electrode subjected to surface treatment of UV irradiation had a conductance of 5.6×10⁻³ (1/Ω), and a gold source/drain electrode subjected to no surface treatment of UV irradiation had a conductance of 7.5×10⁻⁶ (1/Ω). The large conductance resulted from a significant increase in carrier injection density, and the junction barrier between the conductive electrode and the organic semiconductor material was optimized by UV irradiation.

### EXAMPLE 2

Similar effects were obtained by employing DC plasma exposure in a 0.5 Pa argon atmosphere as the adjustment means.

### EXAMPLE 3

The surface of a gold electrode was subjected to surface treatment with UV irradiation (UV cleaning) as the adjustment means. Then, an evaporated pentacene film (thickness of 100 nm) was formed thereon, and a metal electrode was formed on the surface of the evaporated pentacene film. Current-voltage characteristics were evaluated for the case of the treated metal surface, resulting in positive rectification characteristics. These characteristics were resulted from significantly different behaviors in carrier injection, and the junction barrier between the conductive electrode and the organic semiconductor material could be optimized by UV irradiation.

The organic semiconductor device of the present invention can increase a density of carriers flowing between the organic semiconductor material and the conductive electrode and can inject the carriers with high efficiency. The organic semiconductor device has good device characteristics and can be used for a diode, a thin film transistor, a junction type transistor, a solar cell, or the like.

This application claims priority from Japanese Patent Application No. 2004-091573 filed on Mar. 26, 2004, which is hereby incorporated by reference herein.

1. An organic semiconductor device comprising:
an organic semiconductor material, and
a conductive electrode contacting with the organic semiconductor material,
wherein a quasi Fermi level of the organic semiconductor material and a Fermi level of the conductive electrode are optimized by using adjustment means, and a junction barrier between the organic semiconductor material and the conductive electrode is controlled.

2. A method of producing an organic semiconductor device including an organic semiconductor material and a conductive electrode contacting with the organic semiconductor material, comprising:
optimizing a quasi Fermi level of the organic semiconductor material and a Fermi level of the conductive electrode by adjustment means; and
controlling a junction barrier between the organic semiconductor material and the conductive electrode.

3. A method of producing an organic semiconductor device according to claim 2, wherein the adjustment means is one selected from the group consisting of photoirradiation, plasma exposure, heating, washing with a liquid, and rubbing treatment.

4. A method of producing an organic semiconductor device according to claim 2, wherein the adjustment means is carried out on at least one of a surface of the organic semiconductor material and a surface of the conductive electrode.

5. A method of producing an organic semiconductor device according to claim 2, wherein the conductor electrode is composed of at least one metallic substance selected from the group consisting of gold, silver, platinum, copper, aluminum, and calcium.

6. A method of producing an organic semiconductor device according to claim 2, further comprising determining a height of the junction barrier by measuring a surface electrostatic potential of the organic semiconductor material formed on the conductive electrode.

7. A method of producing an organic semiconductor device according to claim 2, wherein a height of the junction barrier is 0.5 eV or less.

8. A method of producing an organic semiconductor device according to claim 2, wherein the organic semiconductor device is one selected from the group consisting of a diode, a thin film transistor, a junction type transistor, and a solar cell.
